(19) United States
(12) Patent Application Publication
(10) Pub. No.: US 2019/0019932 A1
(43) Pub. Date: Jan. 17, 2019

(54) LIGHT EMITTING DEVICE

(71) Applicant: Toyoda Gosei Co., Ltd., Kiyosu-shi (JP)

(72) Inventors: Seiji Yamaguchi, Kiyosu-shi (JP); Hiroshi Ito, Kiyosu-shi (JP); Takayoshi Yajima, Kiyosu-shi (JP)

(21) Appl. No.: 16/012,619

(22) Filed: Jun. 19, 2018

(30) Foreign Application Priority Data
Jul. 13, 2017 (JP) 2017-137449

(51) Int. Cl. H01L 33/64; H01L 25/075; H01L 33/56; H01L 33/62

(52) U.S. Cl. CPC H01L 33/647; H01L 33/62; H01L 33/56; H01L 25/0753

(57) ABSTRACT

A light emitting device includes: a base member; an insulating layer stacked in a surface of the base member, the insulating layer having excellent adhesion to a sealing glass; and a light emitting element mounted on the insulating layer, wherein: the insulating layer is formed by directly supplying a material to the surface of the base member; and porosity of the insulating layer is 10% or less.

### CROSS-REFERENCE TO RELATED APPLICATION(S)

This application is based upon and claims the benefit of priority from Japanese Patent Application No. 2017-137449, filed on Jul. 13, 2017, the entire contents of which are incorporated herein by reference.

### BACKGROUND

### 1. Field of the Invention

The invention relates to an improved light emitting device.

### 2. Description of the Related Art

A light emitting device includes a substrate portion, a light emitting element which is mounted in a surface of the substrate portion, and a transparent sealing portion which covers the light emitting element to be closely attached to the surface of the substrate portion. In a case where a short-wavelength and high-power light emitting element is used, the sealing portion is desirably made of glass in order to prevent the sealing portion from being degraded and turned yellow (Japanese Patent No. 5307364). A glass sealing portion (“sealing glass” in this specification) and the substrate portion are closely adhered to protect the light emitting element.

In the substrate portion, an alumina substrate is used from the viewpoint of light reflectance, economical efficiency, insulation, airtightness, and adhesion to the sealing glass. In general, the alumina substrate is made of a sintered body. On the other hand, the substrate portion is required to have a function of dissipating heat of the light emitting element. Therefore, the alumina substrate desirably secures mechanical rigidity and insulation as a substrate, and is formed as thin as possible.

In the light emitting device of the related art, for example, a plurality of light emitting elements are mounted in the alumina substrate of 25 mm×25 mm, necessary wirings are disposed, and the light emitting elements are covered by the sealing glass of 20 mm×20 mm In such a light emitting device, for example, when the alumina substrate has the thickness of 0.25 mm, mechanical rigidity and sufficient heat dissipation are provided in the substrate portion.

The alumina substrate is generally attached and held on a base member which is made of a metallic material excellent in a thermal conductivity (see JP-A-2012-160534).

A substrate portion of a current light emitting device is required to be increased in area. As the substrate portion is formed in a large area, much more light emitting elements can be mounted. With this configuration, a high-power light emitting device is obtained. It is considered that a number of light emitting elements are mounted in the large-area substrate portion to switch the elements in use.

Then, the inventors has widen the alumina substrate having, for example, a thickness of 0.25 mm used in the related art, and accordingly widen the sealing area using a sealing glass also. For example, the alumina substrate (thickness: 0.25 mm) is formed in a square plate shape of 35 mm×35 mm in a plan view, and covered with the sealing glass of a square shape of 30 mm×30 mm in a plan view. With the light emitting device of such a configuration, the alumina substrate is bent due to a difference of linear expansion coefficients of the sealing glass and the alumina substrate as the light emitting device is cooled down after being manufactured. Further, there occur cracks and damage. The reason is because mechanical rigidity of the alumina substrate is insufficient. Therefore, the thickness of the alumina substrate is made four times bigger to prevent the bending of the alumina substrate. However, since the alumina substrate becomes thick unnecessarily, heat dissipation from the light emitting element is insufficiently drawn out.

When the sealing glass is formed, the alumina substrate is not supported by a base member, a deformation of the alumina substrate caused by the difference of the linear expansion coefficients of the sealing glass and the alumina substrate is not possible to be prevented from the base member. The reason is because the alumina substrate and the base member are unbearable to a molding temperature of the sealing glass in a state where the alumina substrate and the base member are attached.

### SUMMARY

The inventors have sincerely studied to solve the problems described above, and as a result have reached the following invention.

According to a first aspect of the invention, there is provided a light emitting device including: a base member; an insulating layer stacked in a surface of the base member, the insulating layer having excellent adhesion to a sealing glass; and a light emitting element mounted on the insulating layer, wherein: the insulating layer is formed by directly supplying a material to the surface of the base member; and porosity of the insulating layer is 10% or less.

According to the light emitting device of the first aspect defined above, an insulating material such as alumina is directly supplied to the surface of the base member to form an insulating layer such as an alumina layer. Since the base member has sufficient mechanical rigidity even though the insulating layer is formed to be thin, the substrate portion formed of a stacked body of the base member and the insulating layer also has sufficient mechanical rigidity. Since the insulating material is directly supplied to the surface of the base member, a strong physical bonding is obtained between these two, and a high thermal resistance is also obtained. Therefore, it is possible to form the sealing glass with respect to the substrate portion formed of the stacked body of the base member and the insulating layer.

With a thin insulating layer, it is possible to secure sufficient heat dissipation from the light emitting element.

The insulating layer is also required the heat dissipation (thermal conductivity), the insulation, and the airtightness together with adhesion to the sealing glass.

Herein, the porosity of the insulating layer formed by directly supplying an insulating material to the surface of the base member is set to 10% or less, the heat dissipation, the insulation, and the airtightness can be secured together.

When the porosity of the insulating layer exceeds 10%, a ratio of a void in the insulating layer is increased, the thermal conductivity is decreased, and the airtightness becomes insufficient. When water enters the void, the insulation is hardly secured. The adhesion to the sealing glass layer depends on a material selected for the insulating layer. A linear expansion coefficient of the material of the insulating layer is desirably set to a value as close as that of the material of the sealing glass.

A lower limit of the porosity is not particularly limited. The lower limit value may be set to 0.1%.

The porosity is obtained as follows. The insulating layer is cut in a vertical direction with respect to the base member, and a microphotograph of the cut surface is captured. The captured image is subjected to image processing to integrate the area of a space included in a predetermined area, and a ratio of both areas is calculated.

According to a second aspect of the invention, in the light emitting device of the first aspect, the insulating layer is made of alumina, the base member is made of a material having a thermal conductivity higher than that of alumina, and the insulating layer includes a portion having a maximum length of 35 mm or more in a plan view, and a film thickness of the insulating layer is 0.5 mm or less.

The invention defined in the second aspect has the following meaning. In the light emitting device of the related art, there is a concern that the alumina substrate is deformed or damaged when the width of the thin alumina substrate for the heat dissipation is widened to 35 mm or more, and accordingly the width of the sealing glass is also widened. Since this problem is based on the difference of the linear expansion coefficient of the alumina substrate and the sealing glass, it is not possible to avoid the problem as long as the alumina substrate is thin.

In the invention, even when the substrate portion having the same operation as the alumina substrate (that is, a thin insulating layer (thickness: 0.5 mm or less) to secure sufficient heat dissipation) is widened to 35 mm or more, and accordingly a coating area of the sealing glass layer is increased, the insulating layer is not deformed. The reason is because particles (or atoms) of the insulating layer are bonded to the surface of the base member at a particle level (or an atomic level), the insulating layer and the base member are bonded to each other in a more firm manner, and the insulating layer is supported by the base member.

According to a third aspect of the invention, in the light emitting device of the second aspect, a thickness of the insulating layer is 0.25 mm or less.

A fourth aspect of the invention is defined as follows. In other words, in the light emitting devices defined in the second or the third aspects, when the insulating layer is made of alumina and the base member is formed by an aluminum plate member having a good adhesiveness to alumina, a thickness of the aluminum plate is set to 0.25 mm or more. When the thickness is less than 0.25 mm, the mechanical rigidity of the base member becomes insufficient. Therefore, there is a concern that even the base member is deformed by a stress caused by the difference of the linear expansion coefficients of the sealing glass and the insulating layer. The thickness of the aluminum plate is desirably set to 1 to 30 mm.

A maximum length of the base member is set to 35 mm or more, and a maximum length of the sealing glass is set to 28 mm or more in consideration of the relation between the base member and the sealing glass.

### BRIEF DESCRIPTION OF THE DRAWINGS

The present invention will become more fully understood from the detailed description given hereinbelow and the accompanying drawing which is given by way of illustration only, and thus is not limitative of the present invention and wherein:

FIGS. 1A to 1C are views illustrating a configuration of a light emitting device 1 of an embodiment of the invention, wherein FIG. 1A is a plan view, FIG. 1B is a front view, and FIG. 1C is a side view;

FIGS. 2A and 2B are views illustrating a configuration of a light emitting device 11 of another embodiment of the invention, wherein FIG. 2A is a plan view and FIG. 2B is a front view; and

FIGS. 3A to 3C are views illustrating a light emitting device 21 of still another embodiment of the invention, wherein FIG. 3A is a plan view, FIG. 3B is a front view, and FIG. 3C is a side view.

### DETAILED DESCRIPTION OF THE INVENTION

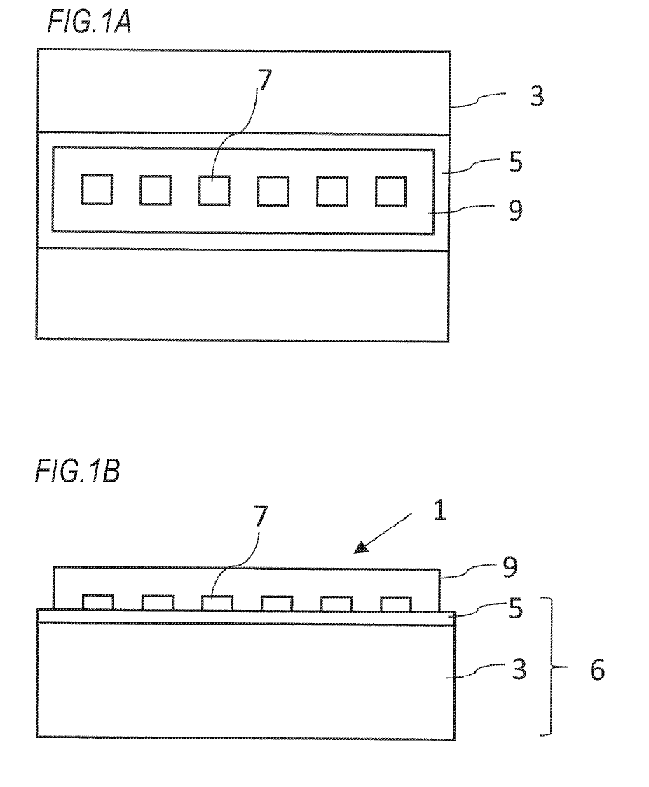

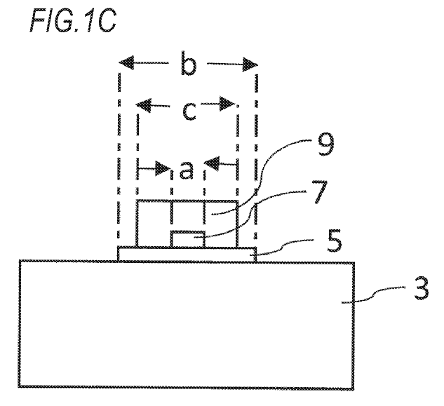

Next, embodiments of the invention will be described. A light emitting device 1 of an embodiment includes a base member 3, an insulating layer 5, light emitting elements 7, and a sealing glass 9 as illustrated in FIGS. 1A to 1C. The base member 3 and the insulating layer 5 constitute a substrate portion 6.

Any material of the base member 3 may be selected as long as the material has a good thermal conductivity. For example, a metallic material such as aluminum, copper, steel, and an alloy thereof may be used. An inorganic material such as aluminum nitride may be used. In order to increase a high heat radiation, the rear surface (a surface opposite to the light emitting elements 7) of the base member 3 is made wide in area (heat radiation surface). For example, fins may be provided.

In the base member 3, sufficient mechanical rigidity is required as a substrate portion of the light emitting device 1. The mechanical rigidity means rigidity necessary for the light emitting device 1 to exert its own function under the use environments of the light emitting device 1, and also means mechanical rigidity for preventing a deformation caused by a difference of a linear expansion coefficient from other members. A thickness and a structure may be arbitrarily selected according to a material in order to secure the mechanical rigidity.

A shape of the base member is arbitrarily selected according to a use and a purpose of the light emitting device. A via hole may be provided.

The insulating layer 5 is formed in all or part of the surface of the base member 3.

In the example of FIGS. 1A to 1C, the insulating layer 5 is formed in a band shape in almost the center portion of the surface of the base member 3.

In this example, alumina is used as a material of the insulating layer 5, but the material is not limited thereto. Any material may be used as long as the material is used as a base layer of an LED. As another material of the insulating layer 5, aluminum nitride, yttria, zirconia, and titania may be used.

A thickness of the insulating layer 5 is desirably made as thin as possible within a range in which the insulation is secured. For example, the thickness may be 0.01 mm to 0.50 mm. Preferably, the thickness is 0.05 mm to 0.25 mm.

The insulating layer 5 of a film shape is formed by directly supplying a material onto the surface of the base member 3. As such a formation method, there are well-known stacking techniques such as spray coating, vapor deposition, sputtering, cold sputtering, and electrochemical processing on a metal surface, or filming techniques. A mask is used in an arbitrary portion of the surface of the base member 3 to form the insulating layer 5.

In the insulating layer 5 thus formed, particles (or atoms) are combined in the surface of the base member 3. Therefore, a high thermal resistance is provided together with a high mechanical strength.

When porosity of the insulating layer 5 is set to 10% or less, a high thermal conductivity is achieved in the insulating layer, and insulation and airtightness are secured.

A shape of the insulating layer 5, that is, a coating shape of the base member 3 may be arbitrarily designed according to the use of the light emitting device.

The light emitting elements 7 are mounted in the insulating layer 5. As the light emitting element 7, a white light emitting element of a so-called phosphor method may be employed in which a light emitting surface of an ultraviolet-light emitting LED chip is coated with a wavelength conversion layer. Of course, a light-emitting color may be arbitrarily selected, and there is no need to form the entire light emitting element 7 mounted in the insulating layer 5 with the same specification.

Any surface mounting method such as a flip-chip method and a face-up method may be employed as a mounting method of the light emitting element 7.

A well-known wiring is formed in the insulating layer 5 to supply necessary power to the light emitting element 7.

Any glass material of the sealing glass 9 can be selected as long as a glass transition point is lower than a heat resisting temperature of the light emitting element 7. For example, ZnO—B₂O₃—SiO₂ may be employed. A glass used in the sealing glass 9 is a glass which is formed in a softening state by heating, and differs from a glass formed by a sol-gel method. In the sol-gel glass, a large volume change occurs at the time of forming. Further, cracks are easily generated, and it is difficult to form a thick glass film. Therefore, the problem can be avoided when the glass is softened by heat, and fused to the insulating layer 5. While the sol-gel glass has a concern of degradation in airtightness due to small cavities therein, the glass of the embodiment has no problem in securely sealing the light emitting element 7.

A linear expansion coefficient of the material of the sealing glass 9 is desirably set to a value as close as that of the insulating layer 5 or the base member 3.

### Embodiments

A first embodiment of the invention will be described with reference to FIGS. 1A to 1C.

A surface of the base member 3 made of an aluminum plate in a rectangular shape (a thickness of 10 mm and a side of 50 mm) in a plan view is subjected to surface treatment (a surface treatment process is a spray coating). A fin may be formed in the rear surface of the base member 3, in which the thickness including the fin is 10 mm. In this case, a thickness of a rectangular top plate may be 1.2 mm.

In a portion between the facing sides in the surface of the base member 3, and preferably in the center portion, the alumina insulating layer 5 of a width of 30 mm between the facing sides is formed in a film shape of 0.05 mm thick by a dense spray coating. In other words, a maximum width of the insulating layer is 50 mm. It can be seen that the porosity of the insulating layer 5 is 3% from a microphotograph of a vertical cross section of the obtained insulating layer 5.

Wirings are provided in the insulating layer 5, and the light emitting elements 7 are mounted in an equal interval by a flip-chip method.

A width “b” of the insulating layer 5 and a width “a” of the light emitting element 7 desirably satisfy a relation of b>2a.

This relation is to secure adhesion between a sealing material and the substrate (insulating film).

A low melting-point glass (zinc-oxide-based glass) is used for the sealing glass 9. A width “c” of the sealing glass 9 is set to 20 mm, a 10 mm margin (non-coated area) is provided between edges of the insulating layer 5.

A height of the sealing glass 9 is set to 0.7 mm.

In the light emitting device 1 of the embodiment, even though the thin insulating layer 5 is made wide in width and the sealing glass 9 is formed wide thereon, there is no deformation in the substrate portion 6. A temperature of forming the sealing glass 9 is set 600° C. After forming, the sealing glass 9 is left in the atmosphere to be naturally radiated.

According to studying of the inventors, when the porosity of the insulating layer 5 exceeds 10%, the airtightness is not secured. There is a concern that the insulation is degraded when water enters a void. When a spray coating is employed as a method of forming the insulating layer by directly supplying a material of the insulating layer to the surface of the base member 3, the porosity of the obtained insulating layer is 5% or less.

Hereinafter, another embodiment of the invention will be described. The same elements as those of the embodiment of FIGS. 1A to 1C will be attached with the same symbols, and the descriptions will be omitted.

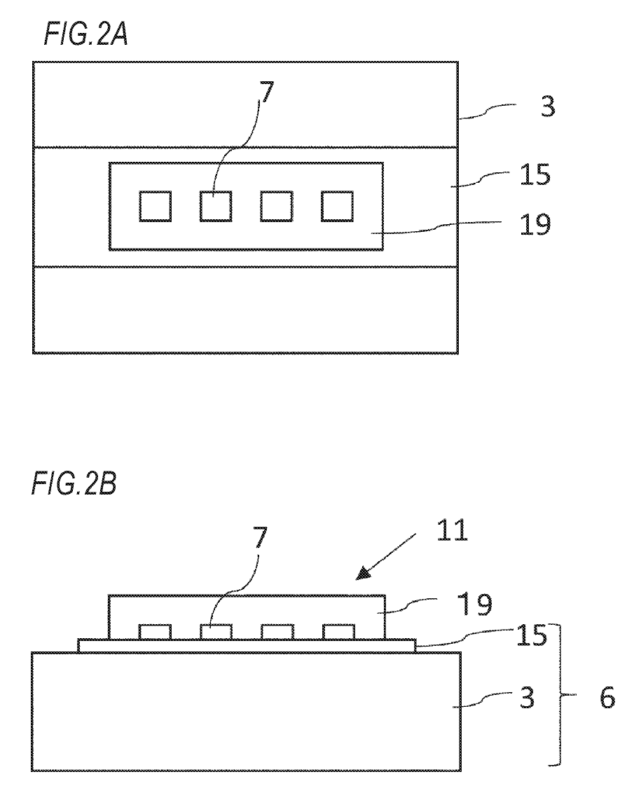

In the light emitting device 11 illustrated in FIGS. 2A and 2B, a thickness of an insulating layer 15 is kept, a coating width is reduced. A maximum length is 35 mm Accordingly, the width of a sealing glass 19 is also recued.

Even in the light emitting device of the embodiment, there is no damage in the substrate portion 6.

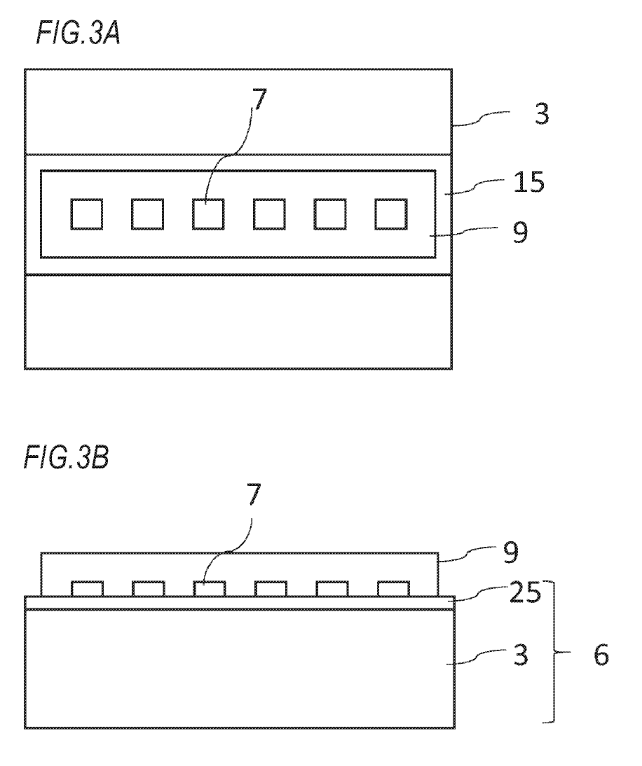

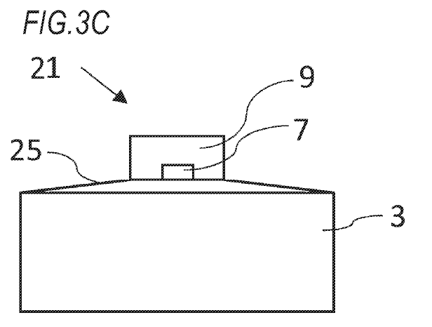

In the light emitting device 21 illustrated in FIGS. 3A to 3C, a thickness of an insulating layer 25 is provided in a slope shape. In a case where the film thickness is provided in the slope, the spray coating is desirably performed. In other words, the thickness of the insulating layer 25 of the center portion is set to the same as illustrated in FIGS. 1A to 1C, and the thickness is gradually made thin as it goes to the side. With this configuration, a distortion caused between the insulating layer and the base member is reduced.

Even in the light emitting device of the embodiment, there is no damage in the substrate portion 6.

The elements of the different embodiments and modifications of the invention described above may be combined to each other except an unrealizable case, and such embodiments are also included in the scope of the invention.

The invention is not limited to any of the explanations of the aspects, embodiments, and modifications of the invention. Various modifications may also be included in the invention in an easily-conceivable scope of a person skilled in the art without departing from the scope of claims.

What is claimed is:

1. A light emitting device comprising:
a base member;
an insulating layer stacked in a surface of the base member, the insulating layer having excellent adhesion to a sealing glass; and
a light emitting element mounted on the insulating layer, wherein:
the insulating layer is formed by directly supplying a material to the surface of the base member; and
porosity of the insulating layer is 10% or less.

2. The light emitting device according to claim 1, wherein:
the insulating layer is made of alumina;
the base member is made of a material having a thermal conductivity higher than that of alumina; and
the insulating layer includes a portion having a maximum length of 35 mm or more in a plan view, and a film thickness of the insulating layer is 0.5 mm or less.

3. The light emitting device according to claim 2, wherein
a thickness of the insulating layer is 0.25 mm or less.

4. The light emitting device according to claim 2, wherein
the base member is made of aluminum and has a thickness of 0.25 mm or more.

5. The light emitting device according to claim 3, wherein
the base member is made of aluminum and has a thickness of 0.25 mm or more.
